(19) United States
(12) Patent Application Publication
(10) Pub. No.: US 2006/0124952 A1
(43) Pub. Date: Jun. 15, 2006

(54) Light emitter

(76) Inventors: Donald J. Milligan, Corvallis, OR (US); Chien-Hua Chen, Corvallis, OR (US); John Paul Harmon, Albany, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/010,073

(22) Filed: Dec. 10, 2004

(51) Int. Cl. H01L 33/00

(52) U.S. Cl. 257/99; 257/91; 257/98

(57) ABSTRACT

One embodiment of a light emitting microchip apparatus includes a substrate having an exposed depression therein and a filament positioned within the exposed depression.

### BACKGROUND

Light emitting microchip systems may emit light therefrom. Light generated by the system may be rejected, i.e., not emitted from the system, by color wheels, ultra violet light filters, and infrared light filters. This rejected light may be dissipated as heat from the system by the use of cooling fans that may utilize additional power in the system and may generate undesirable noise. Moreover, the rejected light may lower an efficiency of and an intensity of light emitted from the microchip system. A system that produces only a desired light would reduce rejected light from the system, thereby reducing the use of cooling fans and increasing an efficiency of the system.

### BRIEF DESCRIPTION OF THE DRAWINGS

FIGS. 1-12 are schematic cross-sectional views of one embodiment of a process of producing one embodiment of a light emitter.

FIG. 13 is a schematic cross-sectional view of another embodiment of a light emitter.

FIG. 14 is a schematic top view of one embodiment of the light emitter of FIG. 12.

FIG. 15 shows one embodiment of an array of light emitters.

### DETAILED DESCRIPTION OF THE DRAWINGS

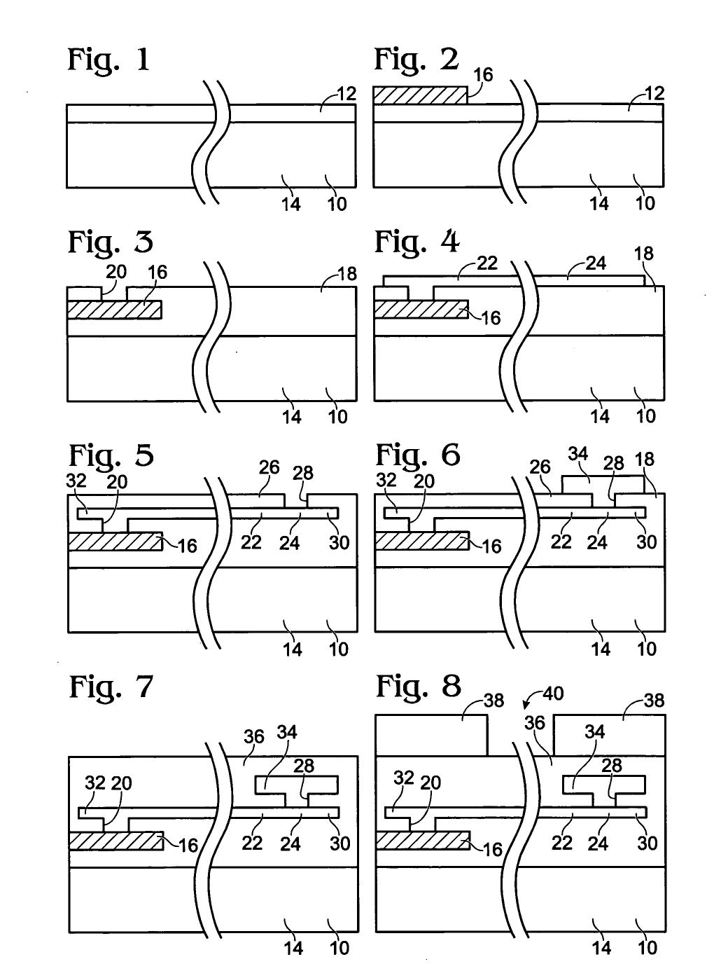

FIGS. 1-12 are schematic cross-sectional views of one embodiment of a process of producing one embodiment of a light emitter 10. Light emitter 10 may include a substrate having an array of exposed depressions and a filament positioned within each depression. The shape of the depression may collimate a portion of the light emitted from the filaments. The filaments may be individually addressed to emit a desired light therefrom.

FIG. 1 shows a first layer, such as a layer of a dielectric material, namely an oxide layer 12, deposited on a substrate, such as on a silicon substrate 14. In other embodiments, the substrate may be glass, ceramic, metal, other semiconductor materials, or other suitable materials or mixtures thereof.

FIG. 2 shows a first conductive layer 16 deposited on oxide layer 12. First conductive layer 16 may be deposited as shown or may be patterned after deposition on layer 12. First conductive layer 16 may be manufactured of any conductive material, such as a metal, namely, gold, copper, titanium, tantalum, tungsten, osmium, aluminum or the like.

FIG. 3 shows a second layer, such as a layer of a dielectric material, namely a second dielectric layer 18, deposited on first dielectric layer 12 and first conductive layer 16. Second dielectric layer 18 may be deposited as to define a via 20. In another embodiment, via 20 may be etched from layer 18 after deposition thereof. Second dielectric layer 18 may be the same material as first dielectric layer 12 such that both layers may be collectively referred to as second dielectric layer 18.

FIG. 4 shows a second conductive layer 22 deposited in via 20 and on second dielectric layer 18. Second conductive layer 22 may or may not be the same material as first conductive layer 16. However, second conductive layer 22 and first conductive layer 16 may be in electrical contact with one another so as to define a continuous electrical pathway therethrough. Second conductive layer 22 may define a filament 24 of light emitter 10, as will be described in more detail below.

FIG. 5 shows a third layer, such as a layer of a dielectric material, namely a third dielectric layer 26, deposited on second conductive layer 22. Third dielectric layer 26 may be deposited so as to define a via 28. In another embodiment, via 28 may be etched from layer 26 after deposition thereof. Third dielectric layer 26 may be the same material as second dielectric layer 18 and first dielectric layer 12 such that all three layers may be collectively referred to as third dielectric layer 26. Via 28 may be positioned at a first end 30 of filament 24 whereas via 20 may be positioned at a second end 32 of filament 24.

FIG. 6 shows a third conductive layer 34 deposited in via 28 and on third dielectric layer 26. Third conductive layer 34 may or may not be the same material as first conductive layer 16 and second conductive layer 22. However, the first, second and third conductive layers may be in electrical contact with one another so as to define a continuous electrical pathway therethrough. Third conductive layer 34 may define an electrical interconnect to first end 30 of filament 24. Similarly, first conductive layer 16 may define an electrical interconnect to second end 32 of filament 24.

FIG. 7 shows a fourth layer, such as a layer of a dielectric material, namely a fourth dielectric layer 36, deposited on third dielectric layer 26. Fourth dielectric layer 36 may be the same material as third dielectric layer 26, second dielectric layer 18 and first dielectric layer 12 such that all four layers may be collectively referred to as fourth dielectric layer 36. Each of the dielectric layers may comprise a material such as silicon oxide, silicon nitride, silicon carbide or the like wherein each of the layers may be manufactured of the same material or each layer may be a material different than the other dielectric layers within the emitter 10.

FIG. 8 shows a pattern layer, such as a patterned layer of photo resist 38 that may be deposited on fourth dielectric layer 36. Photo resist layer 38 may include an exposed region 40 that may be centrally positioned over filament 24 and spaced between first end 30 and second end 32. Photo resist layer 38 may be a material such as poly methylmethacrylate (PMMA), SU-8 epoxy resin or another photo-imagable material.

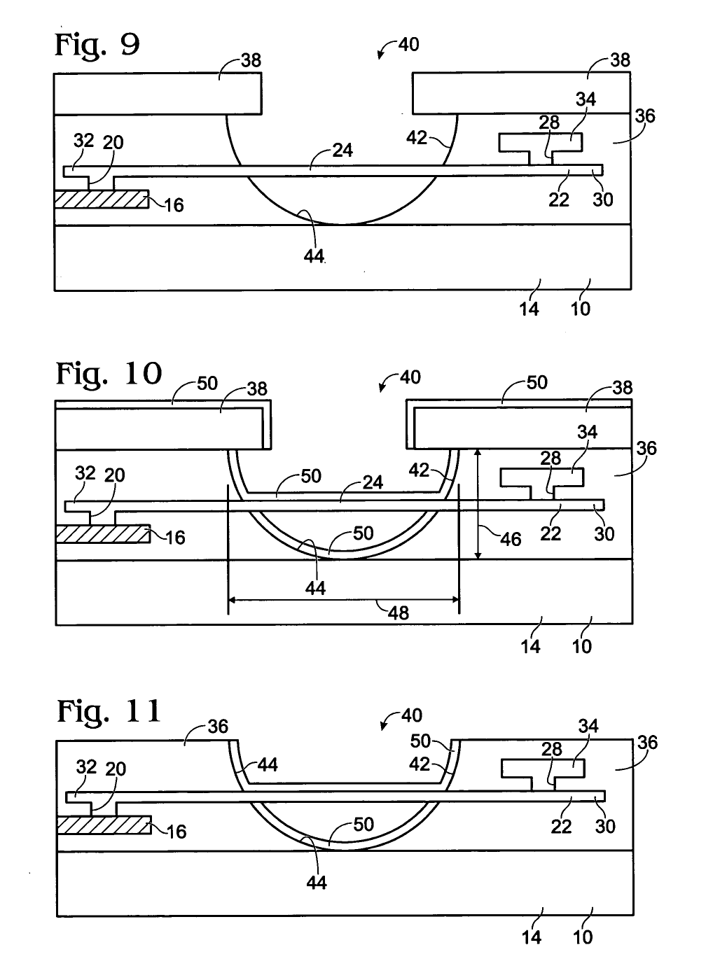

FIG. 9 shows an etching step wherein an open cavity 42 or an exposed depression 42 may be etched into fourth dielectric layer 36. The etching step may comprise a wet etch, a dry etch, or any other step that may form a cavity or depression 42 within fourth dielectric layer 36. The type of etch utilized may determine the shape of cavity 42. Isotropic wet etches may produce substantially semicircular profiles. Dry etches may produce a variety of profiles, such as a substantially anisotropic profile with a corresponding vertical profile to isotropic profiles with a substantially semicircular profile. The dry etch processes can be optimized to create the anisotropic, isotropic, and intermediate profiles, by adjusting the pressure, power and gas flows of the process. Cavity 42 may include a side wall 44 that may define a substantially concave cavity, such as a substantially parabolic shape, a substantially hemispherical shape, a substantially elliptical shape, and a substantially circular shape, for example, that extends below filament 24. A substantially parabolic shape may be defined as a shape that approximates a parabolic shape. A substantially hemispherical shape may be defined as a shape that approximates a hemispherical shape, etc. Due to the relatively width of cavity 42, in this embodiment, the cavity may also be described as being substantially hemispherical in shape. Cavity 42, in the embodiment shown, may have a depth 46 of approximately 2 to 10 micrometers (μms) and a width 48 of approximately 10 to 50 μms.

FIG. 10 shows a reflective layer 50 deposited on all or a part of each of photo resist layer 38, filament 24, and side wall 44 of cavity 42. Reflective layer 50 may be any reflective material such as silver, gold, chrome, aluminum, nickel, titanium, platinum, tungsten, tantalum, paladium molybdenum, osmium, or the like.

FIG. 11 shows removal of photo resist layer 38 such that reflective layer 50 is positioned on filament 24 and side wall 44 of cavity 42.

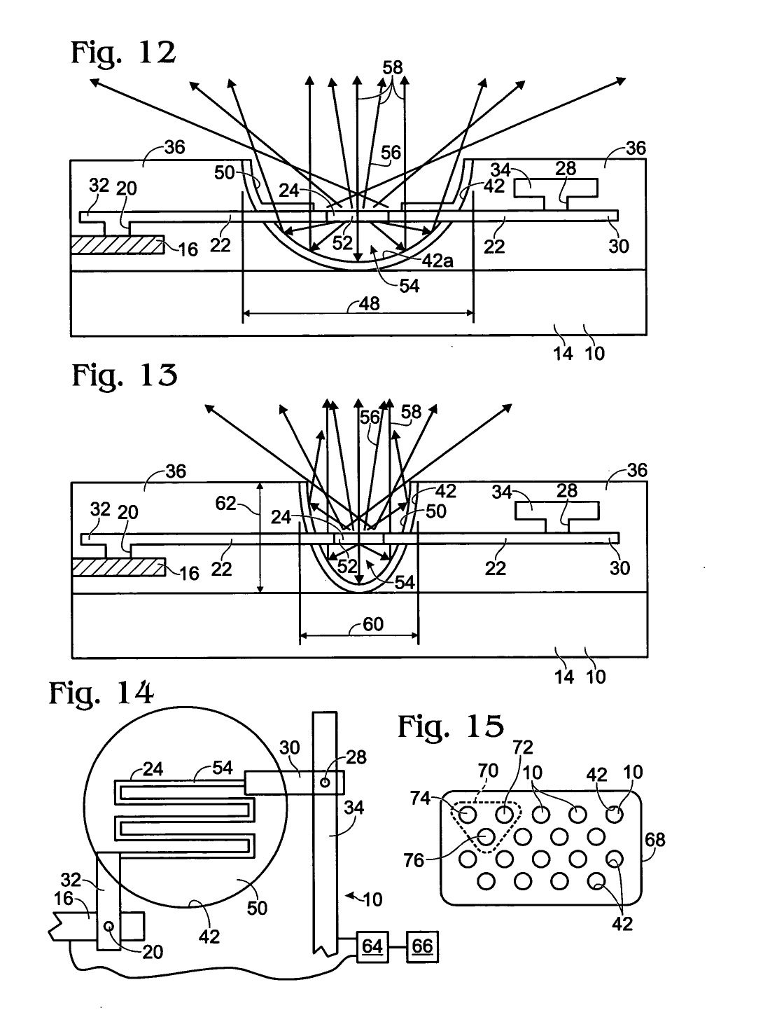

FIG. 12 shows heating of filament 24 to a predetermined temperature, such as a temperature of 1500 to 3500 Kelvin (K). The heating step may be conducted by Joule heating. In an embodiment where reflective coating 50 is a low melting temperature metal, heating of filament 24 may result in evaporation of reflective coating 50 in a central region 52 of filament 24. In another embodiment, heating of filament 24 may result in reflective coating 50 in central region 52 of filament 24 forming an inter-metallic compound with filament 24 in region 52. Accordingly, central region 52 of filament 24 may be exposed such that light may be emitted by filament 24 in central region 52.

Central region 52 of filament 24 may be positioned substantially at a focal point 54 of cavity 42. A portion of light 56 emitted by filament 24 in central region 52, therefore, may be substantially collimated by reflective material 50 on cavity 42 such that a portion of the light is emitted from cavity 42 along substantially parallel lines 58. Moreover, substantially all light 56 emitted by filament 24 may exit cavity 42 such that the efficiency and the intensity of light produced by filament 24 and light emitter 10 may be greater than prior art designs. Additionally, because substantially all light 56 emitted by filament 24 may be emitted from cavity 42, the heat of emitter 10 may be dissipated with light 56 such that noisy cooling fans may not be utilized in the light emitter of the present invention. As shown in this embodiment, filament 24 may be positioned upwardly from a floor 42a of cavity 42 such that light 56 emitted downwardly by filament 24 may be reflected upwardly along parallel lines 58 by reflective layer 50. Filament 24, therefore, may be described as suspended above floor 42a of cavity 42 such that the filament is supported by first end 30 and second end 32 of the filament.

FIG. 13 shows another embodiment of light emitter 10 having a cavity 42 with a width 60 which may be less than width 48 of cavity 42 of FIG. 12. Additionally, cavity 42 of FIG. 13 may have a depth 62 that may be greater than a depth 46 of cavity 42 of FIG. 12. In the embodiment shown, width 60 may be 10 to 30 μms, depth 62 may be 4 to 20 μms, and cavity 42 may define a substantially parabolic shape having focal point 54. Accordingly, light 56 emitted by filament 24 in the embodiment shown in FIG. 13 may be emitted from cavity 42 in a more tightly collimated light beam 58 than light emitted by the light emitter shown in FIG. 12.

FIG. 14 shows a top view of a light emitter 10, which is one of an array of several emitters as shown in FIG. 15, wherein filament 24 extends across open cavity 42 at least three times, and in particular, five times. In this embodiment, the extension of filament 24, which may be described as a thin metal wire, across cavity 42 multiple times may allow an increased amount or intensity of light emitted from light emitter 10 than an embodiment wherein filament 24 extends across cavity 42 only one time. First end 30 of filament 24 is shown connected by via 28 to metal interconnect 34 and second end 32 of filament 24 is shown connected by via 20 to metal interconnect 16. Interconnects 16 and 34 may be connected to a controller 64 and a power source 66 (shown schematically) such that filament 24 may be individually powered to emit light 56 (see FIG. 13) therefrom as may be desired. Accordingly, each filament may be individually addressed such that an intensity of light emitted from said system is variable.

The filaments are heated to a temperature sufficient to spontaneously emit light at the desired wavelengths and intensity. In the preferred embodiment the filaments are heated by Joule heating. The filaments could also be heated by electron beams, lasers or RF. These external heating methods would reduce the heat loss from conduction through the traces.

In one embodiment, filament 24 may be a metallic photonic crystal emitter such that infrared emissions from the filament are reduced or suppressed. A metallic photonic crystal is a periodic structure that has a range of frequencies where light emission is suppressed, called a “photonic bandgap”. The photonic crystal can be made by alternating periodic lines of tungsten or other metals into a face centered cubic (FCC) crystal structure. The crystal should comprise at least six layers of metal with each layer of lines orthogonal to the underlying layer. This structure is sometimes called a “woodpile” photonic bandgap structure. The line's height, pitch and width can be chosen to select the frequencies of light to be suppressed. Metallic photonic crystals could also be made by backfilling in an opal structure and then removing the original opals, creating an inverse opal structure.

Referring again to FIGS. 1-12, each of the layers described herein may be deposited with a thickness and/or width suited for a particular application and/or suited for the particular material used to deposit the particular layer. In one embodiment, first dielectric layer 12 may have a thickness of approximately 2 micrometers (μm). Substrate 14 may have a thickness of approximately 650 μms. First conductive layer 16 may have a thickness of approximately 1 μm. Second dielectric layer 18 may have a thickness of approximately 2 μms. Via 20 may have a width of approximately 1 μm. Second conductive layer 22 may have a thickness of approximately 0.5 μm. Filament 24 may have an exposed length of one pass across cavity 42, of approximately 8 μm. Third dielectric layer 26 may have a thickness of approximately 2 μm. Via 28 may have a width of approximately 1 μm. First end 30 and second end 32 of second conductive layer 22 may be spaced apart a distance of approximately 12 μms. Third conductive layer 34 may have a thickness of approximately 1 μm. Fourth dielectric layer 36 may have a thickness of approximately 2 μm. Photo resist layer 38 may have a thickness of approximately 3 μm. Exposed region 40 may have a width of approximately 10 μm. Reflective layer 50 may have a thickness of approximately 0.1 μm. Of course, other thicknesses of the layers may be utilized as may be desired for a particular application.

FIG. 15 shows one embodiment of an array 68 of light emitters 10. Array 68 may be defined as a light projection system 68. In this schematic representation, only cavities 42 are shown for ease of illustration. Cavities 42 may be diagonally offset from one another so as to allow a tight packing of the light emitters with respect to one another. Other arrangements may be utilized in other embodiments. Three light emitters 10 may be grouped together to define a single pixel 70 (shown in dash lines) wherein one 72 of the light emitters 10 of pixel 70 may emit blue light, another one 74 of the light emitters 10 of pixel 70 may emit green light, and another one 76 of the light emitters 10 of pixel 70 may emit red light. For example, a filament could be made from a photonic crystal designed to emit blue, red or green. The photonic crystals could be tuned to emit the desired frequency of light by adjusting the height, width and/or pitch of the lines of a metallic woodpile structure, or the sphere size of an opal structure. If each pixel contained a red, a blue and a green filament that could be independently controlled, then color emission without filtering could be achieved. Accordingly, grouping of light emitters 10 into three-color-pixels may allow light emitter array 68 to function without use of a color wheel or filters, which may allow an increased intensity and efficiency of light emitted by array 68. In other words, light may not be rejected by the system and substantially all light produced by the array may be emitted therefrom.

In the embodiment shown, each of light emitter 10 may be separated by one another by dielectric layer 36 (see FIG. 12) such that each of the emitters 10 and each of filaments 24 are thermally isolated from one another.

Each of the deposition steps discussed herein may be accomplished by any known means such as chemical vapor deposition, sputtering, spin coating, or the like. Moreover, masks of photo resist or other material may be utilized as will be understood by those skilled in the art. Additionally, other shapes and sizes, and other sequences of fabrication steps, may be utilized to manufacture a light emitter or a light emitter array in accordance with the present invention.

Other variations and modifications of the concepts described herein may be utilized and fall within the scope of the claims below.

We claim:

1. A light emitting microchip apparatus, comprising:
a substrate including an exposed depression therein; and
a filament positioned within said exposed depression.

2. The apparatus of claim 1 wherein said exposed depression defines a side wall, and wherein a reflective material is positioned on at least a portion of said sidewall.

3. The apparatus of claim 1 wherein said filament includes a reflective material positioned on at least a portion thereof.

4. The apparatus of claim 1 wherein said exposed depression is substantially parabolic in shape.

5. The apparatus of claim 4 wherein said filament is positioned substantially at a focal point of said parabolic shape within said exposed depression.

6. The apparatus of claim 1 wherein said exposed depression is substantially hemispherical in shape.

7. The apparatus of claim 1 wherein said substrate is chosen from one of a semiconductor material, glass, ceramic, metal, and mixtures thereof.

8. The apparatus of claim 1 wherein said exposed depression is positioned in a dielectric layer on said substrate.

9. The apparatus of claim 1 wherein said filament extends through said exposed depression and wherein a first end of said filament is connected to a first metal interconnect and a second end of said filament is connected to a second metal interconnect.

10. The apparatus of claim 1 wherein said filament is coated with a reflective material except in a central region thereof.

11. A light emitting microchip apparatus, comprising:
a substrate including an open cavity therein;
a filament positioned within said open cavity; and
a reflective material positioned on at least a portion of an inner surface of said open cavity.

12. The apparatus of claim 11 wherein said open cavity is formed by etching.

13. The apparatus of claim 11 wherein said inner surface of said open cavity defines a concave reflecting surface.

14. The apparatus of claim 11 wherein light emitted by said filament is substantially collimated by said open cavity.

15. The apparatus of claim 11 further comprising a plurality of open cavities, each having a filament positioned therein and each having a reflective material positioned on at least a portion of an inner surface of said open cavity.

16. The apparatus of claim 15 wherein said plurality of filaments are thermally isolated from one another.

17. The apparatus of claim 11 wherein said open cavity is formed in a layer of dielectric material positioned on said substrate.

18. The apparatus of claim 11 wherein said filament produces a colored light chosen from one of blue light, green light and red light.

19. The apparatus of claim 11 wherein said filament extends across said open cavity.

20. The apparatus of claim 19 wherein said filament extends across said open cavity at least three times.

21. A process of producing a light emitter, comprising:
depositing a dielectric layer on a substrate;
depositing a metal layer on said dielectric layer; and
etching a cavity in said dielectric layer such that a portion of said metal layer is positioned within said cavity.

22. The process of claim 21 wherein said substrate is a semiconductor substrate.

23. The process of claim 21 wherein said portion of said metal layer positioned within said cavity defines a filament.

24. The process of claim 21 further comprising depositing a reflective layer on at least a portion of an inner surface of said cavity.

25. The process of claim 21 further comprising depositing a reflective layer on at least a part of said portion of said metal layer positioned within said cavity.

26. The process of claim 21 wherein said substrate comprises a silicon substrate.

27. The process of claim 21 further comprising, prior to etching said cavity, depositing a second dielectric layer on said metal layer.

28. The process of claim 27 wherein said step of etching a cavity in said dielectric layer comprises depositing a photo resist layer on said second dielectric layer, etching said first and second dielectric layers, and then removing said photo resist layer.

29. The process of claim 28 further comprising, prior to removing said photo resist layer, depositing a reflective layer on a portion of an inner wall of said cavity and on a part of said portion of said metal layer positioned within said cavity.

30. The process of claim 21 wherein said dielectric is chosen from one of silicon oxide and silicon nitride, and said metal is chosen from one of gold, copper, titanium, tantalum, tungsten, osmium and aluminum.

31. The process of claim 21 wherein said cavity defines a substantially parabolic shape and wherein said portion of said metal layer is positioned substantially at a focal point of said parabolic shape.

32. The process of claim 21 wherein said portion of said metal layer positioned within said cavity emits light when a voltage is applied thereacross.

33. A light emitting microchip apparatus, comprising:
a substrate including a plurality of exposed depressions therein; and
a filament positioned within each of said open depressions.

34. The apparatus of claim 33 wherein said exposed depressions each define a side wall, and wherein a reflective material is positioned on at least a portion of each sidewall.

35. The apparatus of claim 33 wherein each filament includes a reflective material positioned on at least a portion thereof.

36. The apparatus of claim 33 wherein each of said exposed depressions are substantially parabolic in shape.

37. The apparatus of claim 36 wherein each of said filaments are positioned substantially at a focal point of said parabolic shape within each of said exposed depressions.

38. The apparatus of claim 33 wherein each of said exposed depressions is substantially hemispherical in shape.

39. The apparatus of claim 33 wherein said substrate comprises a silicon substrate.

40. The apparatus of claim 33 wherein each of said exposed depressions is positioned in a dielectric layer on said substrate.

41. The apparatus of claim 33 wherein a first filament emits blue light, a second filament emits green light, a third filament emits red light, and wherein said first, second and third filaments define a pixel in a light projection system.

42. The apparatus of claim 33 wherein each filament includes a first end that includes a first metal interconnect and a second end that includes a second metal interconnect.

43. The apparatus of claim 33 wherein each of said filaments is coated with a reflective material except in a central region thereof.

44. A light projection system, comprising:
a microchip substrate including a plurality of exposed cavities therein; and
a filament positioned within each of said plurality of exposed cavities.

45. The system of claim 44 wherein each filament is adapted for emitting light therefrom.

46. The system of claim 45 wherein each filament includes a first metal interconnect and a second metal interconnect.

47. The system of claim 44 wherein each cavity defines a shape that substantially collimates a portion of light emitted from said filament positioned therein.

48. The system of claim 44 wherein each filament comprises a metal wire.

49. The system of claim 44 wherein said plurality of filaments collectively produce red, green and blue light, and wherein said system operates in the absence of a color wheel.

50. The system of claim 44 wherein said plurality of cavities are etched in a thin film of dielectric material positioned on said substrate.

51. The system of claim 44 wherein each filament is individually addressed such that an intensity of light emitted from said system is variable.

52. A microchip light emitter, comprising:
means for emitting light; and
means for substantially collimating a portion of light emitted from said means for emitting, said means for substantially collimating positioned on a substrate.

53. The emitter of claim 52 wherein said means for substantially collimating partially surrounds said means for emitting.

54. The emitter of claim 52 wherein said means for substantially collimating light comprises an open cavity in said substrate.

55. The emitter of claim 54 wherein said open cavity defines a substantially parabolic shape.

56. The emitter of claim 54 wherein said open cavity defines a substantially hemispherical shape.

57. The emitter of claim 52 wherein said means for substantially collimating light includes a means for reflecting thereon.

58. The emitter of claim 57 wherein said means for reflecting comprises a layer of reflective material at least partially covering said means for substantially collimating light.

59. The emitter of claim 52 wherein said means for emitting light comprises a filament.

60. The emitter of claim 59 wherein said filament comprises a metallic photonic crystal emitter.
